(19) United States
(12) Patent Application Publication
(10) Pub. No.: US 2026/0335948 A1
(43) Pub. Date: Oct. 29, 2026

(54) PIPE CLEANING METHOD

(71) Applicant: SCREEN Holdings Co., Ltd., Kyoto (JP)

(72) Inventors: Haruki OKAMOTO, Kyoto (JP); Hajime NISHIDE, Kyoto (JP); Kazuma NOGUCHI, Hsinchu (TW)

(21) Appl. No.: 19/552,656

(22) Filed: Feb. 27, 2026

(30) Foreign Application Priority Data
Mar. 10, 2025 (JP) 2025-037153

(51) Int. Cl. B08B 9/032

(52) U.S. Cl. CPC B08B 9/032; B08B 2209/032

(57) ABSTRACT

A substrate processing apparatus includes a holder for holding a substrate, a chemical liquid nozzle for ejecting a chemical liquid toward the substrate, a pure water nozzle for ejecting pure water toward the substrate, a chemical liquid supply line for supplying the chemical liquid to the chemical liquid nozzle, and a pure water supply line for supplying the pure water to the pure water nozzle. A pipe cleaning method includes a first process step of cleaning the chemical liquid supply line by introducing a cleaning solution containing ultrafine bubbles into the chemical liquid supply line and a second process step of cleaning the chemical liquid supply line with the chemical liquid by introducing the chemical liquid into the chemical liquid supply line after the first process step. In the first and second process steps, neither the cleaning solution nor the chemical liquid is supplied to a product substrate.

### CROSS REFERENCE TO RELATED APPLICATION

The present application claims the benefit of priority to Japanese Patent Application No. 2025-37153 filed on Mar. 10, 2025, the content of which is incorporated herein by reference in its entirety.

### TECHNICAL FIELD

The present invention relates to a pipe cleaning method for cleaning pipes of a substrate processing apparatus.

### BACKGROUND ART

In a process of manufacturing a semiconductor substrate (hereinafter, referred to simply as a "substrate"), conventionally, various processings are performed on the substrate by using a substrate processing apparatus. When particles are deposited inside pipes, valves, and the like (hereinafter, referred to simply as "pipes and the like") of the substrate processing apparatus, a processing liquid containing the particles is disadvantageously supplied to the substrate. Then, by flowing a predetermined liquid in the pipes and the like for a long time (in other words, by performing flushing), cleaning is performed inside the pipes and the like. In an apparatus disclosed in Japanese Patent Application Laid Open Gazette No. 2021-2551, pipes are cleaned by using DIW (De-Ionized Water) or hydrogen peroxide solution, and in an apparatus disclosed in Japanese Patent Application Laid Open Gazette No. 2022-148186, pipes are cleaned by using ammonia, isopropyl alcohol, hydrogen peroxide solution, or ozone water. Further, Japanese Patent No. 7355255 discloses a method of cleaning pipes of a pure water supply line in a wafer cleaning apparatus by introducing pure water containing micro nano bubbles into the pure water supply line.

In recent years, with refinement of the semiconductor manufacturing process, the cleanliness required for each constituent component of the substrate processing apparatus becomes higher. In a chemical liquid supply line for supplying a chemical liquid to a nozzle, since the chemical liquid directly acts on a substrate surface, especially high cleanliness is required. In a case where cleaning is performed by flushing in which the chemical liquid flows continuously in the chemical liquid supply line, it takes a long time and a large amount of chemical liquid is consumed until predetermined cleanliness (which is evaluated by the number of particles contained in the chemical liquid having passed through the chemical liquid supply line) is achieved. Further, even when the flushing of the chemical liquid is performed, there are some cases where the physical force acting on the particles adhering to the pipes and the like is too insufficient to sufficiently remove the particles.

### SUMMARY OF THE INVENTION

It is an object of the present invention to appropriately clean a chemical liquid supply line while reducing the amount of chemical liquid consumed in pipe cleaning.

A first aspect of the present invention is intended for a pipe cleaning method for cleaning a pipe of a substrate processing apparatus, in the pipe cleaning method according to the first aspect of the present invention, the substrate processing apparatus includes a holder for holding a substrate, a chemical liquid nozzle for ejecting a chemical liquid toward the substrate, a pure water nozzle for ejecting pure water toward the substrate, a chemical liquid supply line for supplying a chemical liquid to the chemical liquid nozzle, and a pure water supply line for supplying pure water to the pure water nozzle, and the pipe cleaning method includes a) cleaning the chemical liquid supply line by introducing a cleaning solution containing ultrafine bubbles into the chemical liquid supply line and b) cleaning the chemical liquid supply line with the chemical liquid by introducing the chemical liquid into the chemical liquid supply line after the operation a), and in the pipe cleaning method, neither the cleaning solution nor the chemical liquid is supplied to a product substrate in the operations a) and b).

According to the present invention, it is possible to efficiently and appropriately clean the chemical liquid supply line by the ultrafine bubbles and reduce the amount of chemical liquid consumed in pipe cleaning. Further, by removing the ultrafine bubbles remaining inside the chemical liquid supply line by introducing the chemical liquid thereto, it is possible to prevent any defect from occurring in a pattern on the product substrate due to the ultrafine bubbles.

A second aspect of the present invention is intended for the pipe cleaning method according to the first aspect, and in the pipe cleaning method according to the second aspect of the present invention, the chemical liquid supply line includes a storage tank capable of storing a liquid and a circulation line for taking the liquid inside the storage tank out from one end thereof and returning the liquid into the storage tank from the other end, and in the pipe cleaning method, the storage tank and the circulation line forms a circulation flow path in which the liquid is circulated, the cleaning solution flows in the circulation flow path in the operation a), and the chemical liquid flows in the circulation flow path in the operation b).

A third aspect of the present invention is intended for the pipe cleaning method according to the second aspect, and in the pipe cleaning method according to the third aspect of the present invention, the operation a) includes a1) introducing the cleaning solution into the circulation flow path and circulating the cleaning solution in the circulation flow path, a2) discharging the cleaning solution from inside the circulation flow path to outside the circulation flow path, and a3) repeating the operations a1) and a2).

A fourth aspect of the present invention is intended for the pipe cleaning method according to the third aspect, and in the pipe cleaning method according to the fourth aspect of the present invention, the operation b) includes b1) introducing the chemical liquid into the circulation flow path and circulating the chemical liquid in the circulation flow path, b2) discharging the chemical liquid from inside the circulation flow path to outside the circulation flow path, and b3) repeating the operations b1) and b2).

A fifth aspect of the present invention is intended for the pipe cleaning method according to the second aspect (or any one of the second to fourth aspects), and in the pipe cleaning method according to the fifth aspect of the present invention, the substrate processing apparatus further includes a plurality of chemical liquid nozzles including the chemical liquid nozzle and a plurality of chambers in which the plurality of chemical liquid nozzles are disposed, respectively, and the chemical liquid supply line further includes a plurality of branch lines branching out from the circulation line to be connected to the plurality of chemical liquid nozzles, respectively, and in the pipe cleaning method, the cleaning solution is introduced into at least one of the plurality of branch lines in the operation a).

A sixth aspect of the present invention is intended for the pipe cleaning method according to the second aspect (or any one of the second to fifth aspects), and in the pipe cleaning method according to the sixth aspect of the present invention, a first connection line for supplying the cleaning solution generated by using an ultrafine bubble generator into the storage tank and a second connection line for returning the cleaning solution from inside the storage tank to the ultrafine bubble generator are provided, and the cleaning solution is circulated between the storage tank and the ultrafine bubble generator in parallel with circulation of the cleaning solution inside the circulation flow path in the operation a).

A seventh aspect of the present invention is intended for the pipe cleaning method according to the first aspect (or any one of the first to sixth aspects), and in the pipe cleaning method according to the seventh aspect of the present invention, the cleaning solution becomes available in the operation a) by attaching an ultrafine bubble generator to the chemical liquid supply line, and the ultrafine bubble generator is removed from the chemical liquid supply line before supplying a chemical liquid from the chemical liquid nozzle to a product substrate held by the holder after the operation a).

An eighth aspect of the present invention is intended for the pipe cleaning method according to the first aspect (or any one of the first to seventh aspects), and in the pipe cleaning method according to the eighth aspect of the present invention, the cleaning solution is pure water containing the ultrafine bubbles.

A ninth aspect of the present invention is intended for the pipe cleaning method according to any one of the first to eighth aspects, and the pipe cleaning method according to the ninth aspect of the present invention is performed when the substrate processing apparatus is installed in an installation location after conveying the substrate processing apparatus from a manufacturing location to the installation location.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a view showing a layout of a substrate processing apparatus;

FIG. 2 is a view showing a configuration of a chemical liquid supply line and the like;

FIG. 3 is a flowchart showing an operation flow of a pipe cleaning process;

FIG. 4 is a view used for explaining the pipe cleaning process; and

FIG. 5 is another view used for explaining the pipe cleaning process.

### DETAILED DESCRIPTION

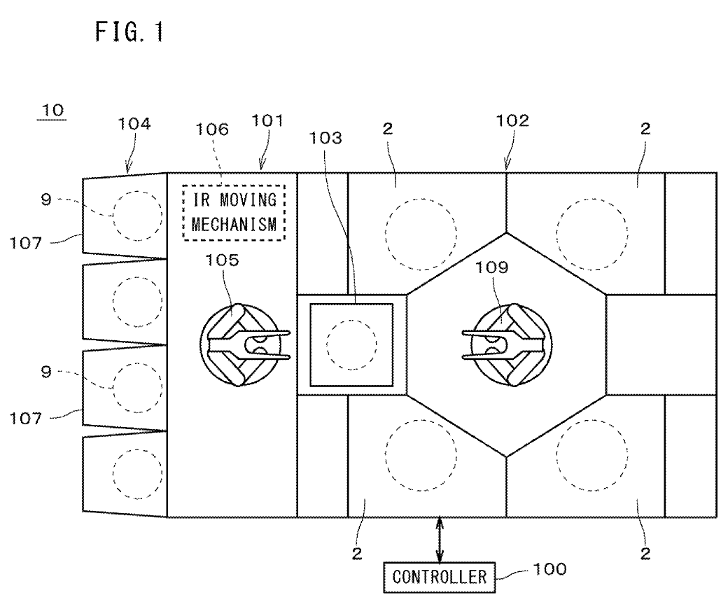

FIG. 1 is a view showing a layout of a substrate processing apparatus 10. The substrate processing apparatus 10 is a system for processing a disk-like semiconductor substrate 9 (hereinafter, referred to simply as a "substrate 9"). The substrate 9 is a product substrate (i.e., a substrate in the course of manufacturing a semiconductor product) from which a semiconductor product is to be eventually taken out. In the present specification, when a substrate is referred to simply as a "substrate 9", the substrate refers to a product substrate and does not include a substrate which is not to become a semiconductor product (a so-called dummy substrate).

The substrate processing apparatus 10 includes a controller 100, an indexer block 101, and a processing block 102 coupled with the indexer block 101. The controller 100 is implemented when a computer having a CPU, a memory, and the like executes a predetermined program, and performs general control of the substrate processing apparatus 10. Part of or the whole of the controller 100 may be implemented by a programmable logic controller (PLC) or the like.

The indexer block 101 includes a carrier holding part 104, an indexer robot 105, and an IR moving mechanism 106. The carrier holding part 104 holds a plurality of carriers 107 each of which can accommodate a plurality of substrates 9. The plurality of carriers 107 (e.g., FOUPs) are held by the carrier holding part 104 while being arranged in a predetermined carrier arrangement direction. The IR moving mechanism 106 moves the indexer robot 105 in the carrier arrangement direction. The indexer robot 105 performs an unloading operation for unloading the substrate 9 from the carrier 107 and a loading operation for loading the substrate 9 into the carrier 107. The substrate 9 is transferred in a horizontal posture by the indexer robot 105. A pass part 103 is provided between a center robot 109 described later in the processing block 102 and the indexer robot 105, and the indexer robot 105 transfers the substrate 9 between the pass part 103 and the carriers 107. In the pass part 103, the substrate 9 is temporarily held in the horizontal posture.

The processing block 102 includes a plurality of (e.g., four or more) processing units 2 for processing the substrate 9 and a center robot 109. The plurality of processing units 2 are so arranged as to surround the center robot 109 in a plan view. Two or more processing units 2 may be layered in an up-and-down direction. In the plurality of processing units 2, various processings are performed on the substrate 9. The center robot 109 passes the substrate 9 from/to the pass part 103. Further, the center robot 109 performs a loading operation for loading the substrate 9 into the processing unit 2 and an unloading operation for unloading the substrate 9 from the processing unit 2. The center robot 109 also transfers the substrate 9 among the plurality of processing units 2. The substrate 9 is transferred in the horizontal posture by the center robot 109.

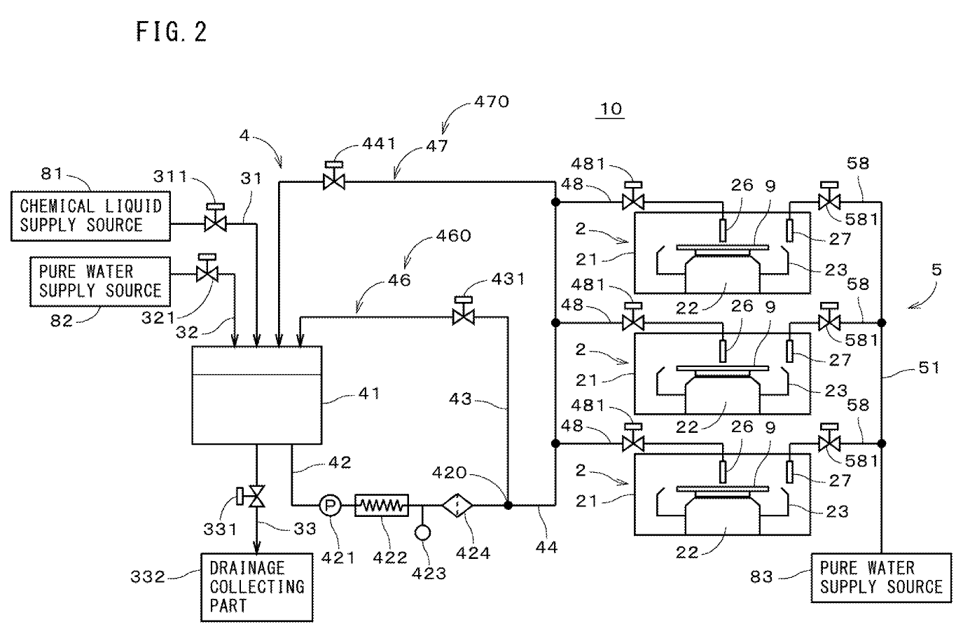

FIG. 2 is a view showing a configuration of the plurality of processing units 2, and a chemical liquid supply line 4 and a pure water supply line 5 which will be described later. FIG. 2 shows part of a configuration of the processing units 2 in a cross section of a plane including a predetermined central axis. In each of the processing units 2, performed is a single-substrate processing for processing the substrate 9 one by one.

The processing unit 2 includes a chamber 21, a spin chuck 22, a cup part 23, a chemical liquid nozzle 26, and a pure water nozzle 27. The chamber 21 is a container (also referred to as a housing) which forms a processing space for the substrate 9, and the spin chuck 22, the cup part 23, the chemical liquid nozzle 26, and the pure water nozzle 27 are disposed inside the chamber 21. The spin chuck 22 is a holder for holding the substrate 9, and in the exemplary case shown in FIG. 2, the spin chuck 22 holds the substrate 9 in the horizontal posture from below by a chuck part having a substantially disk-like shape around the central axis along the up-and-down direction. The chuck part is, for example, a vacuum chuck and comes into contact with a center portion of a lower main surface of the substrate 9 to adsorb the substrate 9. The chuck part may be a mechanical chuck or the like. A rotating mechanism is disposed below the chuck part. The rotating mechanism has a shaft and an electric motor and rotates the substrate 9 together with the chuck part around the central axis. The holder for holding the substrate 9 is preferably the spin chuck 22 and may be any other structure such as the chuck part or the like which is not rotated.

The cup part 23 is an annular member around the central axis and arranged around the spin chuck 22 along the entire circumference in a circumferential direction. The cup part 23 covers a side and a lower side of the substrate 9 held by the spin chuck 22 and receives the liquid spattering from the rotating substrate 9 toward the periphery. The cup part 23 is at rest in the circumferential direction regardless of whether the substrate 9 is rotated or still. On a bottom of the cup part 23, provided is a drainage port (not shown) for discharging the liquid received by the cup part 23 to outside the chamber 21. In the exemplary case shown in FIG. 2, the cup part 23 is movable in the up-and-down direction by a cup moving mechanism having an electric motor, a ball screw, and the like. The cup part 23 may have a plurality of cups layered in a radial direction.

The chemical liquid nozzle 26 is supported by a not-shown chemical liquid nozzle moving mechanism. The chemical liquid nozzle moving mechanism has, for example, an electric motor, a ball screw, and the like and moves the chemical liquid nozzle 26 in a substantially horizontal direction between a supply position above the substrate 9 held by the spin chuck 22 and an escape position outside the substrate 9 in the radial direction. The chemical liquid nozzle 26 may be attached to a rotatable arm. As described later, the chemical liquid nozzle 26 ejects the chemical liquid toward the substrate 9. At the time of ejection of the chemical liquid, the chemical liquid nozzle 26 may be continuously or intermittently moved above the substrate 9 or may be stopped at a predetermined position above the substrate 9 (for example, above the center of the substrate 9). The same applies to the pure water nozzle 27 described later.

The pure water nozzle 27 is supported by a not-shown pure water nozzle moving mechanism. The pure water nozzle moving mechanism has, for example, an electric motor, a ball screw, and the like and moves the pure water nozzle 27 in the substantially horizontal direction between the supply position above the substrate 9 held by the spin chuck 22 and the escape position outside the substrate 9 in the radial direction. As described later, the pure water nozzle 27 ejects pure water toward the substrate 9.

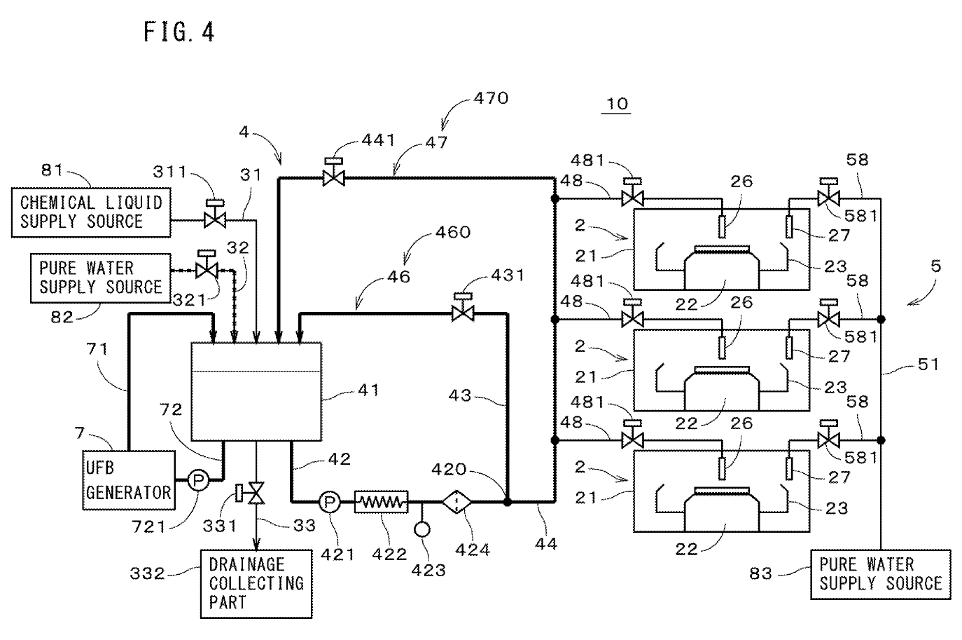

The substrate processing apparatus 10 further includes a chemical liquid supply line 4 and a pure water supply line 5. In the present specification, each of the chemical liquid supply line 4 and the pure water supply line 5 is a flow path for a liquid, most of which consists of pipes. The same applies to a chemical liquid introduction line 31, a pure water introduction line 32, a take-out line 42, a first return line 43, a second return line 44, a branch line 48, a discharge line 33, an introduction line 51, and a branch line 58 described later, which are constituent components of the chemical liquid supply line 4 or the pure water supply line 5. FIG. 4 shows only partial configuration of the chemical liquid supply line 4 and the pure water supply line 5.

The chemical liquid supply line 4 supplies the chemical liquid to the plurality of chemical liquid nozzles 26 in the plurality of processing units 2, respectively. The chemical liquid supply line 4 includes a storage tank 41, a take-out line 42, a first return line 43, a second return line 44, and a plurality of branch lines 48. The storage tank 41 is capable of storing a liquid. A chemical liquid supply source 81 is connected to the storage tank 41 through the chemical liquid introduction line 31. In the chemical liquid introduction line 31, provided is a valve 311. During substrate processing described later, the chemical liquid is supplied and stored into the storage tank 41 from the chemical liquid supply source 81.

A pure water supply source 82 is also connected to the storage tank 41 through the pure water introduction line 32. In the pure water introduction line 32, provided is a valve 321. During pipe cleaning described later, pure water (DIW) is supplied and stored into the storage tank 41 from the pure water supply source 82. One end of the discharge line 33 is connected to a bottom of the storage tank 41. The other end thereof is connected to a drainage collecting part 332. By opening the valve 331 of the discharge line 33, the liquid inside the storage tank 41 can be discharged to the drainage collecting part 332.

One end of the take-out line 42 is connected to a lower portion of the storage tank 41. In the take-out line 42, provided is a pump 421, and the liquid inside the storage tank 41 is taken out to the take-out line 42 by a liquid feed operation of the pump 421 to flow in the take-out line 42. The other end of the take-out line 42 is a node 420 to which one end of the first return line 43 and one end of the second return line 44 are connected. In other words, the take-out line 42 branches to the first return line 43 and the second return line 44 at the node 420, and the liquid flows into the first return line 43 and the second return line 44. In the first return line 43 and the second return line 44, provided are valves 431 and 441, respectively.

The other end of the first return line 43 is connected to the storage tank 41, and the liquid flowing in the first return line 43 is returned into the storage tank 41. The take-out line 42 and the first return line 43 forms a first circulation line 46 for taking out the liquid inside the storage tank 41 from one end thereof and returning the liquid into storage tank 41 from the other end thereof. The other end of the second return line 44 is connected to the storage tank 41, and the liquid flowing in the second return line 44 is returned into the storage tank 41. The take-out line 42 and the second return line 44 forms a second circulation line 47 for taking out the liquid inside the storage tank 41 from one end thereof and returning the liquid into storage tank 41 from the other end thereof. In the chemical liquid supply line 4, the storage tank 41 and the first circulation line 46 forms a first circulation flow path 460 for circulating the liquid and the storage tank 41 and the second circulation line 47 forms a second circulation flow path 470 for circulating the liquid. During the substrate processing, the chemical liquid continuously flows in each of the first circulation flow path 460 and the second circulation flow path 470.

In the take-out line 42, the pump 421, a heater 422, a thermometer 423, and a filter 424 are provided in this order from the storage tank 41 toward the node 420. The pump 421 performs a liquid feed operation so as to flow the liquid inside the storage tank 41 in each of the first circulation flow path 460 and the second circulation flow path 470. The heater 422 heats the liquid flowing in the take-out line 42 as necessary. During the substrate processing, the heater 422 heats the chemical liquid flowing in the take-out line 42. The thermometer 423 measures the temperature of the liquid flowing in the take-out line 42. Actually, the heater 422 is controlled on the basis of a measurement temperature of the thermometer 423. The filter 424 removes an unnecessary substance contained in the liquid.

The plurality of branch lines 48 are connected to the plurality of chemical liquid nozzles 26 in the plurality of processing units 2, respectively. In each of the branch lines 48, an end portion on the opposite side to the chemical liquid nozzle 26 is connected to the second return line 44. Thus, the plurality of branch lines 48 branch from the second circulation line 47 to be connected to the plurality of chemical liquid nozzles 26, respectively. In each branch line 48, provided is a valve 481. By opening the valve 481, the liquid flowing in the second circulation flow path 470 is supplied to the chemical liquid nozzle 26.

The pure water supply line 5 includes an introduction line 51 and a plurality of branch lines 58. The introduction line 51 is connected to a pure water supply source 83 (which may be the same as the pure water supply source 82) and pure water is introduced into the introduction line 51. The plurality of branch lines 58 branch from the introduction line 51 to be connected to the plurality of pure water nozzles 27 in the plurality of processing units 2, respectively. In each of the branch lines 58, provided is a valve 581. By opening the valve 581, the pure water inside the introduction line 51 is supplied to the pure water nozzle 27.

During the substrate processing in the substrate processing apparatus 10, in the chemical liquid supply line 4, the chemical liquid is supplied and stored into the storage tank 41 from the chemical liquid supply source 81. Further, the chemical liquid continuously flows in each of the first circulation flow path 460 and the second circulation flow path 470. At that time, the heater 422 is controlled on the basis of the measurement temperature of the thermometer 423, and the chemical liquid having an almost constant temperature flows in the first circulation flow path 460 and the second circulation flow path 470. By opening the valve 481 in each branch line 48, the chemical liquid flowing in the second circulation flow path 470 is supplied to the chemical liquid nozzle 26. Further, the chemical liquid nozzle 26 is disposed at the supply position above the substrate 9. The chemical liquid is thereby ejected from the chemical liquid nozzle 26 toward the substrate 9.

The chemical liquid is, for example, hydrofluoric acid, sulfuric acid, acetic acid, nitric acid, hydrochloric acid, aqueous ammonia, hydrogen peroxide solution, organic acid, organic alkali, a surfactant, a corrosion inhibitor, or the like or a mixed solution containing any of those substances. An example of the mixed solution is SPM (sulfuric acid/hydrogen peroxide mixture), SC1 (ammonia hydrogen peroxide mixture), or the like. Further, the chemical liquid may contain pure water as a solvent but a liquid containing only pure water does not serve as a chemical liquid.

In the pure water supply line 5, pure water is introduced from the pure water supply source 83 into the introduction line 51. By opening the valve 581 of each branch line 58, the pure water inside the introduction line 51 is supplied to the pure water nozzle 27. Further, the pure water nozzle 27 is disposed at the supply position above the substrate 9. The pure water is thereby ejected from the pure water nozzle 27 toward the substrate 9. Furthermore, there may be a configuration where the pure water nozzle 27 is disposed at a position deviated from above the substrate 9 and ejects the pure water toward the substrate 9 from this position.

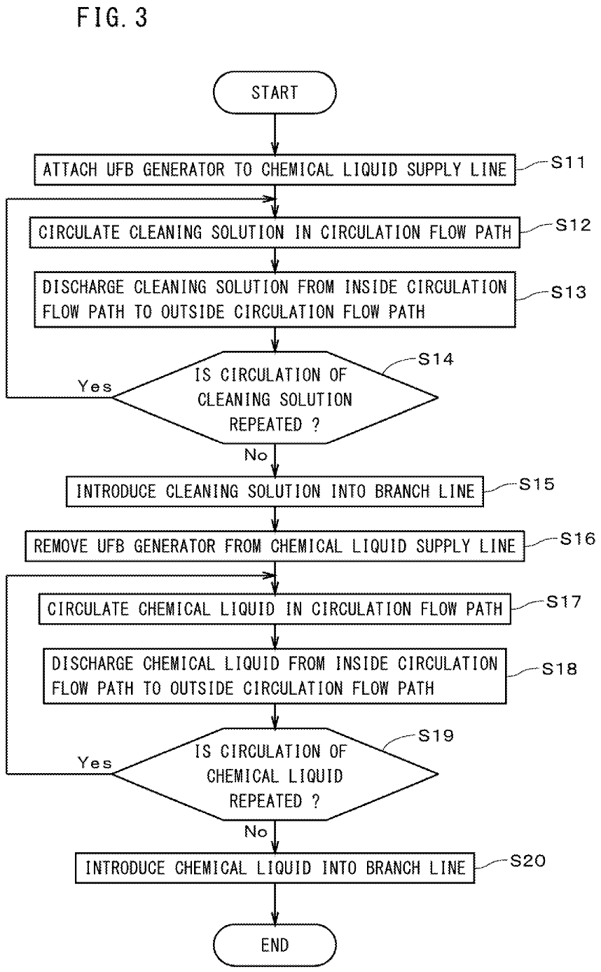

Next, with reference to FIG. 3, a pipe cleaning process for cleaning a pipe of the chemical liquid supply line 4 in the substrate processing apparatus 10 will be described. In FIG. 3, process steps other than Step S11 or S16 described later may be performed by an operation of the operator or by a control of the controller 100. Herein, it is assumed that after conveyance of the substrate processing apparatus 10 from a manufacturing location to an installation location thereof, the pipe cleaning process shown in FIG. 3 is performed at the time of installation (so-called start-up) to the installation location. As described later, the pipe cleaning process may be performed in the manufacturing location of the substrate processing apparatus 10 or may be performed after the installation to the installation location.

In the present pipe cleaning process, used is a cleaning solution containing ultrafine bubbles (hereinafter, referred to simply as "UFBs"). An UFB is a bubble having a diameter smaller than 1μm and is known to have a very long lifetime. The cleaning solution may contain bubbles (micro bubbles each having a diameter not smaller than 1μm and smaller than 100μm, or the like) other than the UFBs, besides the UFBs. A preferable cleaning solution contains UFBs having a density (the number of UFBs per unit volume in the cleaning solution) larger than that of bubbles other than the UFBs. In the present exemplary process, the UFBs are bubbles of air and the cleaning solution is pure water containing the UFBs. The UFBs may be bubbles of gas other than air, and may be, for example, bubbles of ozone gas, carbon dioxide gas, or the like. As described later, the cleaning solution may be a mixture of a liquid other than pure water and the UFBs.

FIG. 4 is a view used for explaining the pipe cleaning process and shows the substrate processing apparatus 10 in which a UFB generator 7 described later is attached to the chemical liquid supply line 4. In the pipe cleaning process, first, the UFB generator 7 is prepared. The UFB generator 7 is an apparatus for generating the UFBs in a liquid and an operator attaches the UFB generator 7 to the chemical liquid supply line 4 in the substrate processing apparatus 10 (Step S11). In the exemplary case shown in FIG. 4, the UFB generator 7 and the storage tank 41 are connected to each other through a first connection line 71 and a second connection line 72. In the second connection line 72, provided is a pump 721.

Subsequently, by opening the valve 321 of the pure water introduction line 32, pure water (DIW) is supplied into the storage tank 41 from the pure water supply source 82. After a predetermined amount of pure water is stored inside the storage tank 41, the valve 321 is closed. In FIG. 4, a thick broken line is superimposed on the pure water introduction line 32. When the pump 721 of the second connection line 72 starts a liquid feed operation, the pure water inside the storage tank 41 is taken out to the second connection line 72 and supplied to the UFB generator 7. The UFB generator 7 generates UFBs in the pure water and obtains a cleaning solution which is pure water containing the UFBs. The cleaning solution is returned into the storage tank 41 through the first connection line 71. In other words, the cleaning solution generated by using the UFB generator 7 is supplied into the storage tank 41 through the first connection line 71 and the cleaning solution inside the storage tank 41 is returned to the UFB generator 7 through the second connection line 72.

Thus, by continuously circulating the cleaning solution between the storage tank 41 and the UFB generator 7 through the first connection line 71 and the second connection line 72, the cleaning solution having high density of UFBs is prepared inside the storage tank 41. In FIG. 4, the first connection line 71 and the second connection line 72 in each of which the cleaning solution flows are each indicated by a thick solid line.

After the cleaning solution inside the storage tank 41 is prepared, by opening the valve 431 of the first return line 43 and the valve 441 of the second return line 44 and starting the liquid feed operation of the pump 421, the cleaning solution inside the storage tank 41 is introduced into the take-out line 42. The flow of the cleaning solution in the take-out line 42 branches to the first return line 43 and the second return line 44 at the node 420. The cleaning solution flowing into the first return line 43 flows up to an end portion on the opposite side to the node 420 and is returned into the storage tank 41. The cleaning solution flowing into the second return line 44 also flows up to an end portion on the opposite side to the node 420 and is returned into the storage tank 41.

At that time, in the first circulation line 46 including the take-out line 42 and the first return line 43, the UFBs contained in the cleaning solution act on particles adhering to the inside of the pipes and the like. In more detail, the UFB in the cleaning solution carries an electric charge (for example, negative electric charge), and the particles inside the pipes and the like, each of which carries an electric charge (for example, positive electric charge) opposite to that of the UFB, adhere to the UFBs and flow together with the cleaning solution. Further, an operation of peeling off the particles adhering to the inside of the pipes and the like can also occur when the UFBs in the cleaning solution pop. Thus, since the UFBs give a physical force to the particles adhering to the inside of the pipes and the like, it becomes possible to efficiently clean the pipes and the like in the first circulation line 46.

Similarly in the second circulation line 47 including the take-out line 42 and the second return line 44, the UFBs contained in the cleaning solution act on the particles adhering to the inside of the pipes and the like, and it becomes possible to efficiently clean the pipes and the like in the second circulation line 47. In FIG. 4, the first circulation line 46 and the second circulation line 47 in which the cleaning solution flows are each indicated by a thick solid line. Actually, the inside of the storage tank 41 is also cleaned by the cleaning solution. Further, in a case where the filter 424 produces an effect on the passage of the UFBs, the present pipe cleaning process may be performed with the filter 424 removed from the take-out line 42. In this case, it is preferable to attach the filter 424 to the take-out line 42 before the circulation of the chemical liquid described later.

In the present exemplary process, the liquid feed operation of the pump 421 continues for a predetermined time, and the cleaning solution is circulated in the first circulation flow path 460 including the storage tank 41 and the first circulation line 46 and the cleaning solution is circulated also in the second circulation flow path 470 including the storage tank 41 and the second circulation line 47 (Step S12). The chemical liquid supply line 4 including the first circulation flow path 460 and the second circulation flow path 470 is thereby cleaned by the cleaning solution. Since the UFB has a very long lifetime as described earlier, even in the long circulation flow path (the first circulation flow path 460 and the second circulation flow path 470), it becomes possible to appropriately clean the whole circulation flow path. Further, in parallel with the circulation of the cleaning solution inside the first circulation flow path 460 and the second circulation flow path 470, the cleaning solution is circulated also between the storage tank 41 and the UFB generator 7. Therefore, the UFBs consumed or extinguished in the circulation of the cleaning solution inside the first circulation flow path 460 and the second circulation flow path 470 are replenished by the UFB generator 7. As a result, it becomes possible to maintain the state where the density of the UFBs is high in the cleaning solution inside the storage tank 41.

After the circulation of the cleaning solution inside the first circulation flow path 460 and the second circulation flow path 470 continues for a predetermined time, the respective liquid feed operations of the pumps 421 and 721 are stopped. The circulation of the cleaning solution inside the first circulation flow path 460 and the second circulation flow path 470 is thereby stopped and the circulation of the cleaning solution between the storage tank 41 and the UFB generator 7 is also stopped. At that time, the valve 431 of the first return line 43 and the valve 441 of the second return line 44 may be closed, or the valve (not shown) provided in the first connection line 71 or the second connection line 72 may be closed.

Subsequently, by opening the valve 331 of the discharge line 33, the cleaning solution (the cleaning solution containing the particles) inside the storage tank 41 is discharged to the drainage collecting part 332. In other words, the cleaning solution inside the first circulation flow path 460 and the second circulation flow path 470 is discharged to outside the circulation flow path (Step S13). Though almost all the cleaning solution inside the storage tank 41 is discharged in the exemplary case, only part of the cleaning solution inside the storage tank 41 may be discharged. After the discharge of the cleaning solution inside the storage tank 41 is completed, the valve 331 of the discharge line 33 is closed.

In the present exemplary process, a set number of times at which a circulation process of the cleaning solution should be repeated in Step S12 is set in advance, and when the number of circulation processes of the cleaning solution (which is the number of repetitions of Step S12, and is once at this point in time) does not reach the set number of times, the circulation process of the cleaning solution is repeated (Step S14). Specifically, the supply of pure water into the storage tank 41 from the pure water supply source 82, the circulation of the cleaning solution between the storage tank 41 and the UFB generator 7, and the circulation of the cleaning solution inside the first circulation flow path 460 and the second circulation flow path 470 are performed. After the circulation of the cleaning solution inside the first circulation flow path 460 and the second circulation flow path 470 continues for a predetermined time, the circulation of the cleaning solution inside the first circulation flow path 460 and the second circulation flow path 470 is stopped and the circulation of the cleaning solution between the storage tank 41 and the UFB generator 7 is also stopped. Then, the operation in Step S13, i.e., the discharge of the cleaning solution inside the storage tank 41 to the drainage collecting part 332 is performed. Thus, the operations in Steps S12 and S13 are repeated (Step S14) until the number of repetitions of the circulation processes of the cleaning solution reaches the set number of times.

After the cleaning solution inside the storage tank 41 is discharged in Step S13, when it is confirmed that the number of repetitions of the circulation processes of the cleaning solution reaches the set number of times (Step S14), the cleaning solution is introduced into the branch lines 48 (Step S15). Specifically, first, the supply of pure water into the storage tank 41 from the pure water supply source 82, the circulation of the cleaning solution between the storage tank 41 and the UFB generator 7, and the circulation of the cleaning solution inside the second circulation flow path 470 are performed. Further, the valve 481 of each branch line 48 is opened, and the cleaning solution flowing in the second circulation flow path 470 is supplied to the chemical liquid nozzle 26. The cleaning solution ejected from the chemical liquid nozzle 26 is received by the cup part 23 and discharged to outside the chamber 21 through the drainage port. The branch line 48 and the chemical liquid nozzle 26 are thereby cleaned by the cleaning solution. At that time, in the chemical liquid supply line 4, since the flow paths (the first circulation flow path 460 and the second circulation flow path 470 in the exemplary case shown in FIG. 4) on the upstream side with respect to the branch line 48 have been cleaned, it is possible to more reliably prevent the branch line 48 and the chemical liquid nozzle 26 from being contaminated by the particles adhering to the flow paths on the upstream side.

The introduction of the cleaning solution into the branch lines 48 continues for a predetermined time. The introduction of the cleaning solution into the plurality of (all the) branch lines 48 may be performed at the same time, or the introduction of the cleaning solution into one or two or more branch lines 48 may be repeated while the branch line 48 is switched. At that time, in order to keep the amount of cleaning solution inside the second circulation flow path 470 to some degree, it is preferable that pure water should be continuously or intermittently supplied (replenished) into the storage tank 41 from the pure water supply source 82. Since the circulation of the cleaning solution between the storage tank 41 to the UFB generator 7 continues in parallel with the introduction of the cleaning solution into the branch lines 48, the density of the UFBs in the cleaning solution can be maintained to some degree.

Further, when the cleaning solution is ejected from the chemical liquid nozzle 26, since no substrate 9 (product substrate) is disposed inside the chamber 21, the cleaning solution does not adhere to the substrate 9. Inside the chamber 21, a substrate which is not to become a semiconductor product (a so-called dummy substrate) may be disposed. Furthermore, there may be a configuration where a mixing valve (multiple valve) or the like is provided in the branch line 48 and the cleaning solution introduced into the branch line 48 does not flow into the chemical liquid nozzle 26 but is discharged outside from the mixing valve.

After the introduction of the cleaning solution into the branch lines 48 continues for a predetermined time, the valve 481 of each branch line 48 is closed and the respective liquid feed operations of the pumps 421 and 721 are stopped. Then, the cleaning solution inside the storage tank 41 is discharged to the drainage collecting part 332. Further, the operator removes the UFB generator 7 from the chemical liquid supply line 4 (Step S16). In the present exemplary process, the UFB generator 7 together with the first connection line 71 and the second connection line 72 is removed.

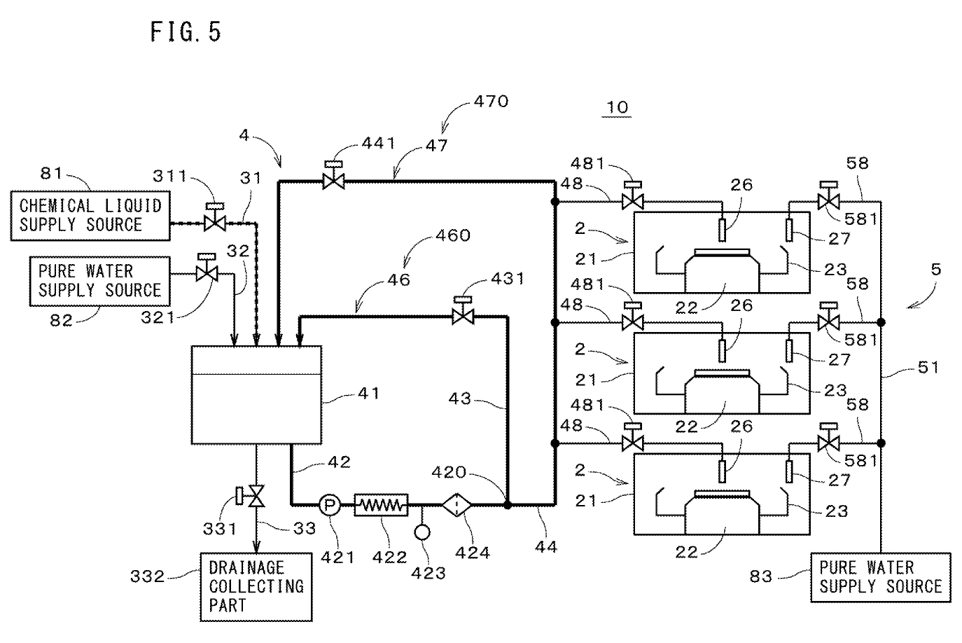

FIG. 5 is another view used for explaining the pipe cleaning process and shows the substrate processing apparatus 10 in which the UFB generator 7 is removed therefrom. Subsequently, by opening the valve 311 of the chemical liquid introduction line 31, the chemical liquid is supplied into the storage tank 41 from the chemical liquid supply source 81. After a predetermined amount of chemical liquid is stored inside the storage tank 41, the valve 311 is closed. In FIG. 5, a thick broken line is superimposed on the chemical liquid introduction line 31 in which the chemical liquid flows.

After the chemical liquid inside the storage tank 41 is prepared, by opening the valve 431 of the first return line 43 and the valve 441 of the second return line 44 and starting the liquid feed operation of the pump 421, the chemical liquid inside the storage tank 41 is introduced into the take-out line 42. The flow of the chemical liquid in the take-out line 42 branches to the first return line 43 and the second return line 44 at the node 420. The chemical liquid flowing into the first return line 43 flows up to the end portion on the opposite side to the node 420 and is returned into the storage tank 41. The chemical liquid flowing into the second return line 44 also flows up to the end portion on the opposite side to the node 420 and is returned into the storage tank 41.

In the first circulation line 46 including the take-out line 42 and the first return line 43, the cleaning solution containing the UFBs which remains inside the pipes and the like is removed by the chemical liquid. Similarly in the second circulation line 47 including the take-out line 42 and the second return line 44, the cleaning solution which remains inside the pipes and the like is removed by the chemical liquid. As a result, during the substrate processing, it is possible to prevent or suppress the chemical liquid containing the UFBs from being supplied to the substrate 9. As a matter of course, by the flow of the chemical liquid, the first circulation line 46, the second circulation line 47, and the storage tank 41 are also cleaned. In FIG. 5, the first circulation line 46 and the second circulation line 47 in which the chemical liquid flows are each indicated by a thick solid line.

In the present exemplary process, the liquid feed operation of the pump 421 continues for a predetermined time, and the chemical liquid is circulated in the first circulation flow path 460 including the storage tank 41 and the first circulation line 46 and the chemical liquid is circulated also in the second circulation flow path 470 including the storage tank 41 and the second circulation line 47 (Step S17). The chemical liquid supply line 4 including the first circulation flow path 460 and the second circulation flow path 470 is thereby cleaned by the chemical liquid. After the circulation of the chemical liquid inside the first circulation flow path 460 and the second circulation flow path 470 continues for a predetermined time, the liquid feed operation of the pump 421 is stopped, and the circulation of the chemical liquid inside the first circulation flow path 460 and the second circulation flow path 470 is thereby stopped.

Subsequently, by opening the valve 331 of the discharge line 33, the chemical liquid inside the storage tank 41 is discharged to the drainage collecting part 332. In other words, the chemical liquid inside the first circulation flow path 460 and the second circulation flow path 470 is discharged to outside the circulation flow path (Step S18). Though almost all the chemical liquid inside the storage tank 41 is discharged in the exemplary case, only part of the chemical liquid inside the storage tank 41 may be discharged. After the discharge of the chemical liquid inside the storage tank 41 is completed, the valve 331 of the discharge line 33 is closed.

In the present exemplary process, a set number of times at which a circulation process of the chemical liquid should be repeated in Step S17 is set in advance, and when the number of circulation processes of the chemical liquid (which is the number of repetitions of Step S17, and is once at this point in time) does not reach the set number of times, the circulation process of the chemical liquid is repeated (Step S19). Specifically, the supply of the chemical liquid into the storage tank 41 from the chemical liquid supply source 81 and the circulation of the chemical liquid inside the first circulation flow path 460 and the second circulation flow path 470 are performed. After the circulation of the chemical liquid inside the first circulation flow path 460 and the second circulation flow path 470 continues for a predetermined time, the circulation of the chemical liquid inside the first circulation flow path 460 and the second circulation flow path 470 is stopped. Then, the operation in Step S18, i.e., the discharge of the chemical liquid inside the storage tank 41 to the drainage collecting part 332 is performed. Thus, the operations in Steps S17 and S18 are repeated (Step S19) until the number of repetitions of the circulation processes of the chemical liquid reaches the set number of times.

After the chemical liquid inside the storage tank 41 is discharged in Step S18, when it is confirmed that the number of repetitions of the circulation processes of the chemical liquid reaches the set number of times (Step S19), the chemical liquid is introduced into the branch lines 48 (Step S20). Specifically, first, the supply of the chemical liquid into the storage tank 41 from the chemical liquid supply source 81 and the circulation of the chemical liquid inside the second circulation flow path 470 are performed. Further, the valve 481 of each branch line 48 is opened, and the chemical liquid flowing in the second circulation flow path 470 is supplied to the chemical liquid nozzle 26. The chemical liquid ejected from the chemical liquid nozzle 26 is received by the cup part 23 and discharged to outside the chamber 21 through the drainage port. The cleaning solution containing the UFBs which remains inside the branch line 48 and the chemical liquid nozzle 26 is thereby removed by the chemical liquid.

The introduction of the chemical liquid into the branch lines 48 continues for a predetermined time. The introduction of the chemical liquid into the plurality of (all the) branch lines 48 may be performed at the same time, or the introduction of the chemical liquid into one or two or more branch lines 48 may be repeated while the branch line 48 is switched. At that time, in order to keep the amount of chemical liquid inside the second circulation flow path 470 to some degree, it is preferable that the chemical liquid should be continuously or intermittently supplied (replenished) into the storage tank 41 from the chemical liquid supply source 81. Since no substrate 9 (product substrate) is disposed inside the chamber 21, the chemical liquid does not adhere to the substrate 9. Further, inside the chamber 21, a substrate which is not to become a semiconductor product (a so-called dummy substrate) may be disposed. Furthermore, there may be a configuration where a mixing valve (multiple valve) or the like is provided in the branch line 48 and the chemical liquid introduced into the branch line 48 does not flow into the chemical liquid nozzle 26 but is discharged outside from the mixing valve.

After the introduction of the chemical liquid into the branch lines 48 continues for a predetermined time, the valve 481 of each branch line 48 is closed and the liquid feed operation of the pump 421 is stopped. With the above-described operations, the pipe cleaning process shown in FIG. 3 is completed. The chemical liquid inside the storage tank 41 may be kept for the processing of the substrate 9 or may be discharged to the drainage collecting part 332. Further, the pipes in the pure water supply line 5 are cleaned by flushing of pure water, or the like.

As described above, the pipe cleaning method shown in FIG. 3 is intended for cleaning of the pipes in the substrate processing apparatus 10, and the substrate processing apparatus 10 includes the holder (the spin chuck 22 in the above-described case) for holding the substrate 9, the chemical liquid nozzle 26 for ejecting the chemical liquid toward the substrate 9, the pure water nozzle 27 for ejecting the pure water toward the substrate 9, the chemical liquid supply line 4 for supplying the chemical liquid to the chemical liquid nozzle 26, and the pure water supply line 5 for supplying the pure water to the pure water nozzle 27. The pipe cleaning method includes a first process step for cleaning the chemical liquid supply line 4 by introducing the cleaning solution containing UFBs (ultrafine bubbles) and a second process step for cleaning the chemical liquid supply line 4 with the chemical liquid by introducing the chemical liquid into the chemical liquid supply line 4 after the first process step. Further, in the first process step and the second process step, neither the cleaning solution nor the chemical liquid is supplied to the product substrate.

In the pipe cleaning method, in the first process step, it is possible to efficiently and appropriately clean the chemical liquid supply line 4 by the UFBs and possible to reduce the amount of chemical liquid consumed in the pipe cleaning (herein, the second process step). Further, by removing the UFBs remaining inside the chemical liquid supply line 4 by the introduction of the chemical liquid, it is possible to prevent any defect from occurring in a pattern on the product substrate due to the UFBs. Furthermore, it becomes possible to shorten a cleaning time needed until the chemical liquid supply line 4 achieves the required cleanliness.

In the above-described substrate processing apparatus 10, the chemical liquid supply line 4 includes the storage tank 41 capable of storing the liquid and the circulation line (the first circulation line 46 and the second circulation line 47 in the above-described configuration) for taking the liquid inside the storage tank 41 out from one end thereof and returning the liquid into the storage tank 41 from the other end thereof. Further, the storage tank 41 and the circulation line forms the circulation flow path (the first circulation flow path 460 and the second circulation flow path 470 in the above-described configuration) in which the liquid is circulated. In this case, in the pipe cleaning method, it is preferable that the cleaning solution should flow in the circulation flow path in the above-described first process step and the chemical liquid should flow in the circulation flow path in the above-described second process step. Thus, by circulating the cleaning solution and the chemical liquid in the circulation flow path, it is possible to appropriately clean the chemical liquid supply line 4 with a small amount of liquid.

Preferably, the above-described first process step includes a step (Step S12) of introducing the cleaning solution into the circulation flow path and circulating the cleaning solution in the circulation flow path, a step (Step S13) of discharging the cleaning solution inside the circulation flow path to outside the circulation flow path, and a step (Step S14) of repeating Steps S12 and S13. It is thereby possible to thoroughly clean the circulation flow path with a small amount of cleaning solution.

Preferably, the above-described second process step includes a step (Step S17) of introducing the chemical liquid into the circulation flow path and circulating the chemical liquid in the circulation flow path, a step (Step S18) of discharging the chemical liquid inside the circulation flow path to outside the circulation flow path, and a step (Step S19) of repeating Steps S17 and S18. It is thereby possible to thoroughly clean the circulation flow path with a small amount of chemical liquid.

In the above-described substrate processing apparatus 10, provided are the plurality of chemical liquid nozzles 26 including the above-described chemical liquid nozzle 26 and the plurality of chambers 21 in which the plurality of chemical liquid nozzles 26 are disposed, respectively. Furthermore, the chemical liquid supply line 4 further includes the plurality of branch lines 48 which branch from the circulation line (the second circulation line 47 in the above-described configuration) to be connected to the plurality of chemical liquid nozzles 26, respectively. In the substrate processing apparatus 10 having such a configuration, in the above-described first process step, by introducing the cleaning solution into the plurality of branch lines 48, it becomes possible to appropriately clean the plurality of branch lines 48. In the pipe cleaning method, only one branch line 48 may be cleaned. In other words, by introducing the cleaning solution into at least one of the pluralities of branch lines 48, it becomes possible to appropriately clean the one branch line 48.

In the above-described substrate processing apparatus 10, provided are the first connection line 71 for supplying the cleaning solution generated by using the UFB generator 7 into the storage tank 41 and the second connection line 72 for returning the cleaning solution inside the storage tank 41 to the UFB generator 7. In this case, in the pipe cleaning method, it is preferable that the cleaning solution should be circulated between the storage tank 41 and the UFB generator 7 in parallel with the circulation of the cleaning solution inside the circulation flow path in the above-described first process step. It is thereby possible to replenish the cleaning solution with the UFBs at the time of cleaning of the chemical liquid supply line 4 with the cleaning solution and possible to more efficiently clean the chemical liquid supply line 4.

In a preferable pipe cleaning method, by attaching the UFB generator 7 to the chemical liquid supply line 4, the cleaning solution can be used in the above-described first process step. After the above-described first process step, the UFB generator 7 is removed from the chemical liquid supply line 4. Thus, in the case where the UFB generator 7 is detachable/attachable from/to the chemical liquid supply line 4, since it is not necessary to provide the UFB generator 7 in each of the substrate processing apparatuses 10, it is possible to reduce the manufacturing cost of the substrate processing apparatus 10 and the cost required for the pipe cleaning. The timing at which the UFB generator 7 is removed from the chemical liquid supply line 4 may be arbitrarily determined and is not limited to before the above-described second process step. In order to reliably prevent any defect from occurring in a pattern on the product substrate due to the UFBs, it is preferable that the UFB generator 7 should be removed from the chemical liquid supply line 4 before the chemical liquid is supplied to the product substrate held by the holder from the chemical liquid nozzle 26.

In the above-described pipe cleaning method, various modifications can be made.

In the above-described preferred embodiment, though the first circulation flow path 460 and the second circulation flow path 470 are cleaned in parallel (at the same time) in each of Steps S12 and S17, the first circulation flow path 460 and the second circulation flow path 470 may be individually cleaned, or only one of the first circulation flow path 460 and the second circulation flow path 470 may be cleaned. In an exemplary case where the first circulation flow path 460 and the second circulation flow path 470 are individually cleaned, first, the first circulation flow path 460 is cleaned in a state where the valve 431 of the first return line 43 is opened and the valve 441 of the second return line 44 is closed. After that, the second circulation flow path 470 is cleaned in a state where the valve 431 of the first return line 43 is closed and the valve 441 of the second return line 44 is opened.

Further, the first circulation flow path 460 and the second circulation flow path 470 may be cleaned after the storage tank 41 is cleaned with the cleaning solution. For example, a predetermined amount of cleaning solution is stored into the storage tank 41 in a state where the pump 421 of the take-out line 42 is stopped. After that, by opening the valve 331 of the discharge line 33, the cleaning solution inside the storage tank 41 is discharged to the drainage collecting part 332 all at once. By repeating the above-described operation, the inside of the storage tank 41 is cleaned. The cleaning of the first circulation flow path 460 and the second circulation flow path 470 after the cleaning of the storage tank 41 is performed in the same manner as that in the above-described preferred embodiment.

Depending on the type of chemical liquid or the like (for example, in the case of using a relatively cheap chemical liquid, or the like), the cleaning solution may be a chemical liquid containing the UFBs. On the other hand, in a case where the cleaning solution is pure water containing the UFBs, the cleaning solution can be prepared cheaply. From the viewpoint of removing the UFBs from inside the chemical liquid supply line 4, it is preferable that the chemical liquid used in the above-described second process step should scarcely contain any UFB. The chemical liquid not passing through the UFB generator 7 can be regarded as a liquid which scarcely contains any UFB.

The cleaning solution does not necessarily need to be circulated between the UFB generator 7 and the storage tank 41. There may be a configuration, for example, where the UFB generator 7 is attached to the pure water introduction line 32 and the pure water containing the UFBs is supplied into the storage tank 41. Further, the UFB generator 7 may be attached to the take-out line 42, the first return line 43, or the second return line 44. Depending on the design of the substrate processing apparatus 10, the UFB generator 7 may be always attached to the chemical liquid supply line 4.

The chemical liquid supply line 4 may not include the circulation flow path or the storage tank 41. For example, the chemical liquid supply line 4 may directly connect the chemical liquid supply source 81 and the chemical liquid nozzle 26, not through any tank or the like. Further, a subtank may be provided between the chemical liquid supply source 81 and the storage tank 41. In the above-described pipe cleaning method, it is possible to appropriately clean the chemical liquid supply line 4 of various aspects.

The above-described pipe cleaning method may be performed in the manufacturing location of the substrate processing apparatus 10, or may be performed in the installation location, after a temporary suspension of the operation (for example, a maintenance or the like), at a resumption of the operation or the like in the substrate processing apparatus 10 which actually performs the substrate processing. On the other hand, during the conveyance from the manufacturing location of the substrate processing apparatus 10 to the installation location, the particles become easier to adhere to the constituent components of the substrate processing apparatus 10. Therefore, it is more preferable that the above-described pipe cleaning method should be performed at the time of installation to the installation location after the conveyance.

The substrate 9 may be a substrate (for example, a glass substrate, a printed circuit board, or the like) other than the semiconductor substrate.

The configurations in the above-described preferred embodiment and variations may be combined as appropriate only if those do not conflict with one another.

While the invention has been shown and described in detail, the foregoing description is in all aspects illustrative and not restrictive. It is therefore understood that numerous modifications and variations can be devised without departing from the scope of the invention.

### REFERENCE SIGNS LIST

4 Chemical liquid supply line
5 Pure water supply line
7 UFB generator
9 Substrate
10 Substrate processing apparatus
21 Chamber
22 Spin chuck
26 Chemical liquid nozzle
27 Pure water nozzle
41 Storage tank
46 First circulation line
47 Second circulation line
48 Branch line
71 First connection line
72 Second connection line
460 First circulation flow path
470 Second circulation flow path
S11 to
S20 Step

1. A pipe cleaning method for cleaning a pipe of a substrate processing apparatus, wherein
said substrate processing apparatus comprises:
a holder for holding a substrate;
a chemical liquid nozzle for ejecting a chemical liquid toward said substrate;
a pure water nozzle for ejecting pure water toward said substrate;
a chemical liquid supply line for supplying a chemical liquid to said chemical liquid nozzle; and
a pure water supply line for supplying pure water to said pure water nozzle,
said pipe cleaning method, comprising:
a) cleaning said chemical liquid supply line by introducing a cleaning solution containing ultrafine bubbles into said chemical liquid supply line; and
b) cleaning said chemical liquid supply line with said chemical liquid by introducing said chemical liquid into said chemical liquid supply line after said operation a),
wherein neither said cleaning solution nor said chemical liquid is supplied to a product substrate in said operations a) and b).

2. The pipe cleaning method according to claim 1, wherein
said chemical liquid supply line comprises:
a storage tank capable of storing a liquid; and
a circulation line for taking said liquid inside said storage tank out from one end thereof and returning said liquid into said storage tank from the other end,
and wherein said storage tank and said circulation line forms a circulation flow path in which said liquid is circulated,
said cleaning solution flows in said circulation flow path in said operation a), and
said chemical liquid flows in said circulation flow path in said operation b).

3. The pipe cleaning method according to claim 2, wherein
said operation a) comprises:
a1) introducing said cleaning solution into said circulation flow path and circulating said cleaning solution in said circulation flow path;
a2) discharging said cleaning solution from inside said circulation flow path to outside said circulation flow path; and
a3) repeating said operations a1) and a2).

4. The pipe cleaning method according to claim 3, wherein
said operation b) comprises:
b1) introducing said chemical liquid into said circulation flow path and circulating said chemical liquid in said circulation flow path;
b2) discharging said chemical liquid from inside said circulation flow path to outside said circulation flow path; and
b3) repeating said operations b1) and b2).

5. The pipe cleaning method according to claim 2, wherein
said substrate processing apparatus further comprises:
a plurality of chemical liquid nozzles including said chemical liquid nozzle; and
a plurality of chambers in which said plurality of chemical liquid nozzles are disposed, respectively, and
said chemical liquid supply line further comprises:
a plurality of branch lines branching out from said circulation line to be connected to said plurality of chemical liquid nozzles, respectively,
and wherein said cleaning solution is introduced into at least one of said plurality of branch lines in said operation a).

6. The pipe cleaning method according to claim 2, wherein
a first connection line for supplying said cleaning solution generated by using an ultrafine bubble generator into said storage tank and a second connection line for returning said cleaning solution from inside said storage tank to said ultrafine bubble generator are provided, and
said cleaning solution is circulated between said storage tank and said ultrafine bubble generator in parallel with circulation of said cleaning solution inside said circulation flow path in said operation a).

7. The pipe cleaning method according to claim 1, wherein
said cleaning solution becomes available in said operation a) by attaching an ultrafine bubble generator to said chemical liquid supply line, and
said ultrafine bubble generator is removed from said chemical liquid supply line before supplying a chemical liquid from said chemical liquid nozzle to a product substrate held by said holder after said operation a).

8. The pipe cleaning method according to claim 1, wherein
said cleaning solution is pure water containing said ultrafine bubbles.

9. The pipe cleaning method according to claim 1, which is performed when said substrate processing apparatus is installed in an installation location after conveying said substrate processing apparatus from a manufacturing location to said installation location.
